(19) United States
(12) Patent Application Publication
(10) Pub. No.: US 2026/0059720 A1
(43) Pub. Date: Feb. 26, 2026

(54) CONVERTER WITH A COOLING CHANNEL AND COOLANT

(71) Applicant: MAGNA Powertrain GmbH & Co KG, Lannach (AT)

(72) Inventor: Josef Schadauer, Wolfsbach (AT)

(21) Appl. No.: 19/104,463

(22) PCT Filed: Aug. 7, 2023
(86) PCT No.: PCT/EP2023/071803

§ 371 Date: Feb. 18, 2025

(30) Foreign Application Priority Data
Aug. 19, 2022 (DE) 10 2022 208 634.1

(51) Int. Cl. H05K 7/20

(52) U.S. Cl. CPC H05K 7/209

(57) ABSTRACT

A converter for converting a fed type of current into another includes at least one power module and at least one cooling body, and has improved transfer of waste heat from the power module to the coolant. The cooling body is at least partially inserted into a cooling channel so that a coolant flowing through the cooling channel can be supplied to the cooling body at least in portions and so that the power module can give off waste heat to the coolant via the cooling body. An inner wall section of the cooling channel situated opposite a pressure area of the cooling body has a spring-like projection element. The projection element acts with a restoring force against the pressure area of the cooling body so that a contact area of the power module and cooling body is increased.

### CROSS-REFERENCE TO RELATED APPLICATIONS

This application is a National Stage of International Application No. PCT/EP2023/071803, filed Aug. 7, 2023, which claims priority to DE 10 2022 208 634.1, filed Aug. 19, 2022. The entire disclosures of each of the above applications are incorporated herein by reference.

### FIELD

The present disclosure relates to a converter for converting one fed-in type of current into another, having at least one power module and having at least one heat sink, wherein the power module and the heat sink are thermally operatively connected to one another, wherein the heat sink is at least partially inserted into a cooling channel such that a coolant flowing through the cooling channel can be supplied to the heat sink at least in sections and such that the power module can give off waste heat to the coolant via the heat sink.

### BACKGROUND

The converter is usually used to convert one type of current, which may be a direct or alternating current, to the respective other type. In this respect, a distinction is made between the converter and the type of conversion, that is to say an input and an output current type: rectifiers convert an alternating current into a direct current, inverters convert a direct current into an alternating current, and frequency converters convert an alternating current into an alternating current with a different frequency and/or amplitude.

A method for this known from practice comprises clocked actuation of the at least one power module, with these usually having semiconductor switches (MOSFETs, IGBTs, etc.). When the semiconductor switches are clocked, the resulting switching and conduction losses generate the waste heat as power losses, which must be dissipated from the power module in order to protect the power module, otherwise the power module may be damaged or destroyed. In this respect, the heat sink intended for the transfer of the waste heat is areally fixed at least in sections to waste heat surfaces of the power module that are provided for this purpose so that the waste heat can effectively pass from the power module into the coolant flowing through the cooling channel.

Document U.S. Pat. No. 7,547,966 B2 discloses a power module whose thermal resistance and overall size is reduced. Said document relates to an insulating substrate with electrode metal layers arranged on it, said layers being connected to both surfaces of a semiconductor, for example by soldering. A metal layer, which is connected to a heat sink by brazing, is arranged on a rear side of the insulating substrate. A heat-emitting side of the heat sink is covered by a housing to form a cooling channel through which a coolant can flow in order to dissipate any waste heat transferred from the semiconductor to the heat sink. According to said document, bolts that connect the housing to the heat sink in a force-fitting manner can be used to fix and securely connect the structure.

However, this usual approach has the disadvantage that mechanical forces are applied to the heat sink due to the force-fitting connection of the housing and the heat sink; with the result that the heat sink can be easily deformed. This does not adversely affect the ability of the heat sink to dissipate waste heat. However, minimal deformations of the heat sink affect a contact surface of the metal layers on the rear side of the substrate and the heat sink. This contact surface is important for the heat transfer of the waste heat in this respect, because the smaller it is, the less waste heat can be transferred from the semiconductor into the heat sink.

### SUMMARY

The present disclosure discloses a converter having an improved heat transfer of the waste heat from the power module to the coolant as claimed in patent claim 1, which is characterized in that that an inner wall portion of the cooling channel has a spring-like projection element, the inner wall portion being situated opposite a pressure surface of the heat sink that is situated opposite the power module, wherein the projection element acts with a restoring force against the pressure surface of the heat sink, such that a contact surface of the power module and heat sink can be increased. The power module usually includes an interconnection of multiple semiconductor switches, which is suitable for carrying out the clocking for converting the fed-in current type into the other. The interconnection may be, for example, a half-bridge or full-bridge circuit, wherein the semiconductor switches are usually MOSFETs or IGBTs made of a common semiconductor material, such as silicon, for example.

The waste heat generated by the clocking is dissipated within the power module to at least one waste heat surface, wherein the heat sink can be fixed to the waste heat surface from the outside, such that the waste heat can pass from the power module into the heat sink. In this respect, a contact surface, which is effective for heat transfer, between the power module and the heat sink results at the contact points of the waste heat surface of the power module and the heat sink. Bends, curvatures or deformations of any kind can reduce the contact surface, and so it is advantageous according to the present disclosure to compensate for and reduce these deformations of the heat sink by way of the restoring force of the projection element, wherein a number of contact points and the contact surface are increased overall. The projection element is also intended to achieve a more uniform and at the same time high surface pressure, such that in principle all contact surfaces are in contact with one another and a thermal transition resistance for the generated waste heat is as low as possible.

According to the present disclosure, the pressure surface of the heat sink is located on a side of the heat sink opposite the waste heat surface; in this respect, the projection element is aligned with and fixed on the inner wall portion of the cooling channel in such a way that the projection element protrudes from the inner wall portion in the direction of the cooling channel and the restoring force of the projection element can act as vertically as possible on the pressure surface of the heat sink and can press it against the waste heat surface of the power module.

The projection element may be designed differently; for example, a helical spring or a coil spring may be suitable as the projection element, wherein optionally a disk spring may also be used as long as the spring or the projection element can apply a restoring force that is large enough to keep the contact surface between the waste heat surface and the heat sink sufficiently large over a useful life of the converter. The strength of the force and its central engaging position on the heat sink enables the waste heat surface of the power module to be compressed more evenly. An even surface pressure is achieved.

Optionally, it is also conceivable to place the projection elements exactly above the switch elements of the power module so that there is also the greatest contact force of the projection element exactly where the most waste heat is generated. Optionally, it would also be possible to define multiple projection elements. However, it would also be possible to design an annular, square or similar projection element instead of a round projection element.

Optionally, a heat-conducting paste can be used between the waste heat surface and the heat sink for improved heat transfer. Due to its viscosity, the heat-conducting paste additionally increases the contact surface, as it is pressed into many gaps, cracks and surface irregularities of the waste heat surface and the heat sink by a contact force of the heat sink against the waste heat surface. Although heat-conducting pastes should have the highest possible thermal conductivity, they are always less thermally conductive than a metallic waste heat surface or a metallic heat sink. This is why it is particularly advantageous according to the present disclosure for an improved thermal operative connection between the power module and the heat sink that the restoring force of the projection element acting on the pressure surface of the heat sink can keep a thickness of the heat-conducting paste as low as possible.

With converters according to the present disclosure, it is optionally possible to use heat-conducting pastes that become particularly effective only above a specific temperature and a specific pressure, because they can be further compressed above these specific values—then, for example, the thickness of such a heat-conducting paste can be reduced from 100 μm to 40 μm if an ambient temperature of 80° C. is exceeded.

According to a particularly cost-effective configuration of the converter according to the present disclosure, provision may be made for the spring-like projection element of the inner wall portion to be formed as a recess of the cooling channel directed in the direction of the pressure surface of the heat sink. The projection element can then be produced by a recess introduced into the cooling channel from the outside, said recess being curved inside the cooling channel in the direction of the pressure surface of the heat sink. In terms of production, this is not very complex, is cost-effective and allows for a simply designed projection element.

The resilient and restoring-force-applying effect of the projection element designed in this way can be achieved by a suitable material selection of an area around the recess or the entire cooling channel. For this purpose, it is particularly suitable to produce the cooling channel from a spring steel with high strength or elasticity, such that the recesses curved or projection elements directed in the direction of the pressure surface of the heat sink can apply a sufficiently high restoring force.

In order to be able to cool the power module particularly effectively, according to an advantageous configuration of the converter according to the present disclosure, provision may be made for two heat sinks to be fixed on two opposite sides of the power module, wherein the restoring force of a projection element acts on the pressure surface of a heat sink in each case. Accordingly, an improved, double cooling effect of the power module can be achieved, such that other power parameters of the converter according to the present disclosure can be adapted. For example, on the one hand, according to this embodiment, an electrical power of the converter can be increased; on the other hand, an average temperature load of the power module can then also be reduced over the useful life of the converter in order to extend this useful life in turn.

According to an advantageous configuration of the converter according to the present disclosure, provision may be made for the first heat sink to be at least partially inserted into an inlet portion of the cooling channel and for the second heat sink to be at least partially inserted into an outlet portion of the cooling channel, such that the coolant can flow through both heat sinks successively. The longer a coolant can flow through a heat sink, the more waste heat can pass into the coolant. Since in practice a size of the power module is often specified by additionally purchased power modules, a heat sink cannot be arbitrarily large in such cases. On the other hand, a maximum increase in the temperature of the coolant is more cost-effective. In this respect, it is advantageous according to this configuration if the power module is cooled twice by the same coolant flow, since a heat transfer of the waste heat of the power module can thus be increased in the same coolant flow.

In order to reduce a size of the converter, according to an advantageous configuration of the converter according to the present disclosure, provision may be made for the at least one power module and the at least one heat sink to be inserted at least partially into the cooling channel together so that both, the power module and the heat sink, can be supplied with the coolant. Power modules that are encapsulated with a resin and are therefore coolant-tight are available. According to this configuration of the power module, it can be inserted directly into the cooling channel with the at least one heat sink and its waste heat surfaces, saving space. According to this configuration, the power module can be better cooled directly by the coolant and indirectly via the heat sink, thereby increasing the performance of the power module and making the converter more space-efficient.

In order to be able to produce the converter according to the present disclosure more cost-effectively, provision may be made, according to an advantageous configuration, for the cooling channel to consist at least in sections of a plastic material. Usually, a plastic material is cheaper and lighter than a metal, and a cooling channel made of a plastic material is easier to produce. However, the technical robustness of the converter according to the present disclosure can be increased despite a cooling channel partly made of a plastic material if, according to a particularly advantageous configuration of the converter according to the present disclosure, provision is made for the cooling channel to consist of a metal at least in an area around the inner wall section having the spring-like projection element. This is particularly true for the area around the power module, as this causes a clock-related high electromagnetic interference emission and a metallic portion or inner wall portion of the cooling channel in the area of the power module can have an electromagnetic shielding effect.

### BRIEF DESCRIPTION OF THE DRAWINGS

Schematic illustrations of the converter according to the present disclosure are shown below by way of example. In the drawings:

FIG. 1 shows a perspective view of a power module,

FIG. 2 shows a sectional view of a converter along the flow direction of the coolant,

FIG. 3 shows a sectional view of a converter transverse to the flow direction of the coolant and

FIG. 4 shows an overall perspective view of a converter having three power modules.

### DETAILED DESCRIPTION

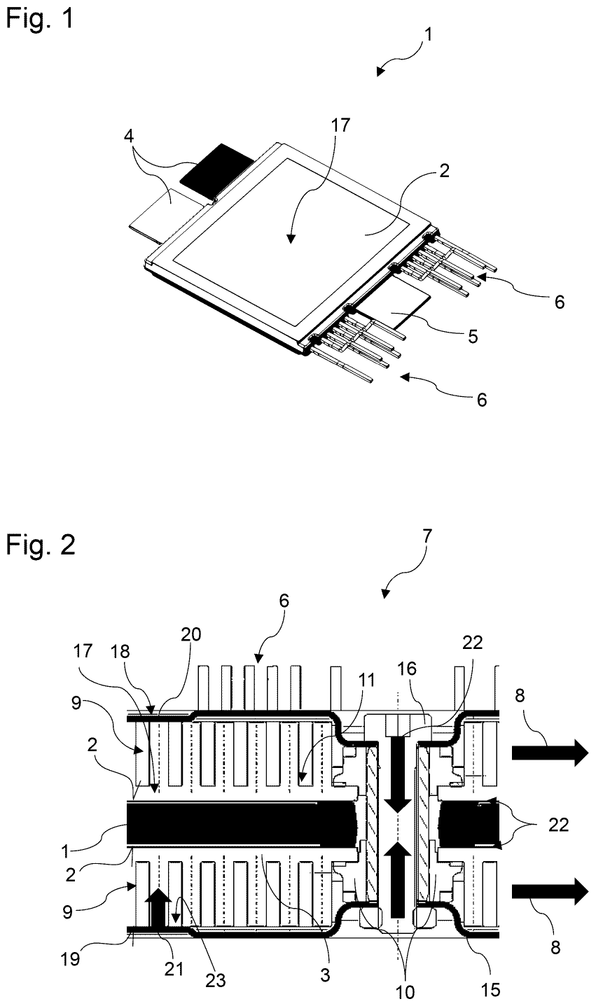

FIG. 1 shows a perspective view of a power module 1 containing two silicon-carbide MOSFETs as semiconductor switches in a half-bridge circuit. The two semiconductor switches are fixed on a carrier plate which is thermally operatively connected to a waste heat surface 2 outside of the power module 1 and to which a heat sink 3 can be fixed.

For the purpose of electrical wiring, two DC terminals 4 and an AC terminal 5 are routed from the power module 1 and are routed within the power module 1 to the corresponding contact points of the semiconductor switches. Multiple auxiliary contacts 6 are also routed out of the power module 1 for actuation of the semiconductor switches and possible measured value acquisition.

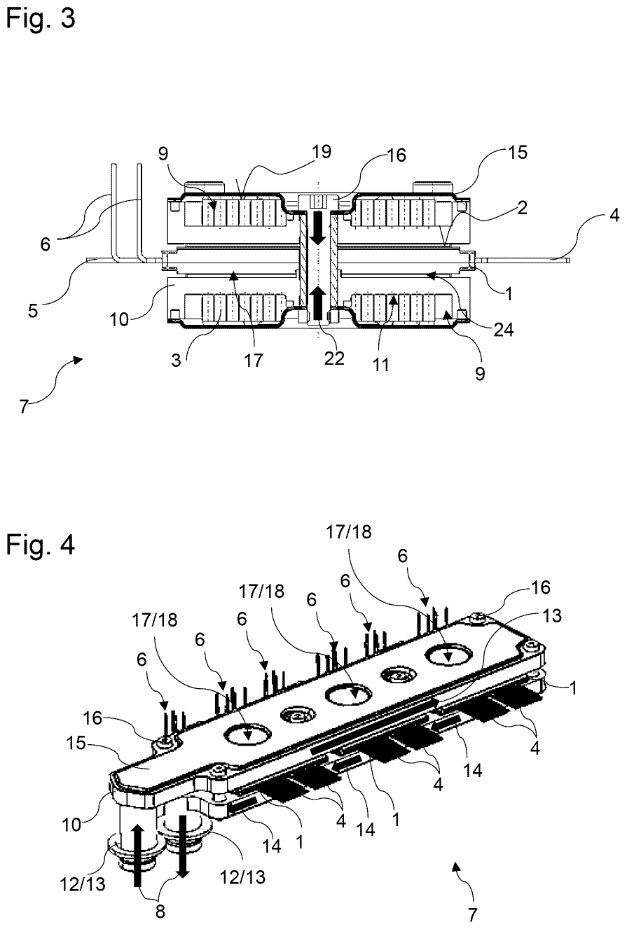

FIG. 2 shows a sectional view of a converter 7 having two partially visible power modules 1 longitudinal to a flow direction 8 of a coolant, FIG. 3 correspondingly shows the converter 7 in a sectional view, transverse to the flow direction 8 of the coolant, and FIG. 4 shows an overall perspective view of the converter 7 having all three power modules 1.

The power modules 1 each have two waste heat surfaces 2 located on two opposite sides of the power module 1 and to each of which a heat sink 3 is fixed, wherein a heat-conducting paste is applied between the heat sink 3 and the waste heat surface 2 for improved heat transfer of the waste heat 2 from the power module 1 into the heat sink 3.

According to this configuration, the two heat sinks 3 of each power module 1 are inserted into a cooling channel 9, wherein the heat sink 3 is pressed by a plastic part 10 consisting of a plastic material against the power module 1, and the plastic part 10 serves overall as a frame for the power modules 1 and both positions and aligns as well as holds said power modules 1.

The structure of the plastic part 10 is designed such that, on the one hand, it forms the lower bottom part of the cooling channel 9, into which the heat sink 3 is inserted via a cooling channel opening 11 into the cooling channel 9, and, on the other hand, has two cooling channel connections 12 for the incoming and outgoing coolant. The coolant can be introduced into the cooling channel 9 through the one cooling channel connection 12, flow along an inlet portion 13 and an outlet portion 13 of the cooling channel 9 and flow out of the cooling channel 9 through the other cooling channel connection 12.

The coolant can flow, along the inlet portion 13, through all the first heat sinks 3 of the power modules 1 and, along the outlet portion 14, through all the second heat sinks 3 of the power modules 1, wherein the sequence of supply to all heat sinks 3 overall ensures that all power modules 1 are cooled approximately equally well. Because the first heat sink 3 of the first power module 1 is supplied by the coolant when a temperature of the coolant is still at its lowest, but the opposite then applies to the second heat sink 3 of the first power module 1; accordingly, the two heat sinks 3 of the last power module 1 are supplied with an approximately equal temperature by the coolant in the cooling sequence. In this respect, the power modules 1 have an approximately equal core temperature to one another due to their two heat sinks 3 on the two opposite sides of the power modules 1 and the cooling sequence. The cooling channel 9 is in each case closed from the top and sealed by two stamped sheets 15 made of spring steel, which are fixed to the plastic part 10 using bolts 16.

The force-fitting fastening of the heat sink 3 by the plastic part 10 to the edge regions of the power module 1 inevitably has the effect that a distance between the heat sink 3 and the waste heat surface 2 in a central region 17 of the waste heat surface 2 is greatest. The consequence is that the waste heat of the power module 1 can be dissipated in the central region 17 to the worst extent and can pass into the heat sink 3, because the power module 1 becomes the warmest due to the placement of the semiconductor switches in the central region 17 and there generates the most waste heat to be dissipated.

According to the present disclosure, the sheet 15 of the cooling channel 9 at the central region 17 of the power module 1 has a recess 18, which forms a projection element 20 inwards in the direction of a pressure surface 19 of the heat sink 3, wherein the projection element 20 has a spring-like elasticity in the direction of the pressure surface 19 of the heat sink 3 due to the material of the sheet 15, such that the projection element 20 can act with a restoring force 21 on the pressure surface 19 without damaging the power module 1 or the heat sink 3 in the process.

The position of the bolts 16 and that of the recesses 18 causes, on the one hand, the fact that the cooling channel 9 is reliably coolant-tight due to the high bolt forces 22 and, on the other hand, that the projection elements 20, formed from an inner wall portion 23 of the sheets 15 through the recesses 18, only act on the pressure surfaces 19 of the heat sink 3 by way of their restoring forces 21, such that a contact surface 24 of the heat sink 3 and the power module 1 is as large as possible and the waste heat from the power module 1 can be effectively dissipated without damaging the power module 1 or the heat sink 3.

### LIST OF REFERENCE SIGNS

1. Power module
2. Waste heat surface
3. Heat sink
4. DC terminal
5. AC terminal
6. Auxiliary contact
7. Converter
8. Flow direction
9. Cooling channel
10. Plastic part
11. Cooling channel opening
12. Cooling channel connection
13. Inlet portion
14. Outlet portion
15. Spring-steel sheet
16. Bolt
17. Power module central region
18. Recess
19. Pressure surface
20. Projection element
21. Restoring force
22. Bolt force
23. Inner wall portion
24. Contact surface

1. A converter for converting one fed-in type of current into another, having at least one power module and having at least one heat sink, wherein the power module and the heat sink are thermally operatively connected to one another, wherein the heat sink is at least partially inserted into a cooling channel such that a coolant flowing through the cooling channel can be supplied to the heat sink at least in portions and such that the power module can give off waste heat to the coolant via the heat sink,
wherein an inner surface of a wall portion of the cooling channel has a spring-like projection element, the inner surface of the wall portion being situated adjacent and facing pressure surface of the heat sink, wherein the heat sink is situated adjacent and facing the power module wherein the projection element acts with a restoring force against the pressure surface of the heat sink such that a contact surface defined between the power module and heat sink can be increased.

2. The converter as claimed in claim 1, wherein the spring-like projection element is formed as a recess in the wall portion of the cooling channel directed in the direction of the pressure surface of the heat sink such that the recess is on an outer surface of the wall portion and the wall portion projects toward the adjacent heat sink.

3. The converter as claimed in claim 1, wherein the two heat sinks are fixed on two opposite sides of the power module wherein the restoring force of a projection element acts in each case on the pressure surface of a heat sink.

4. The converter as claimed in claim 3, wherein the first heat sink is at least partially inserted into an inlet portion of the cooling channel and the second heat sink is at least partially inserted into an outlet portion of the cooling channel such that the coolant can flow through both heat sinks successively.

5. The converter as claimed in claim 1, wherein at least one power module and the at least one heat sink are inserted at least partially into the cooling channel together so that both the power module and the heat sink can be supplied with the coolant.

6. The converter as claimed in claim 1, wherein the cooling channel includes sections of a plastic material.

7. The converter as claimed in claim 1, wherein the cooling channel includes of a metal at least in an area around the inner wall section having the spring-like projection element.

8. The converter as claimed in claim 1, wherein the projection element is disposed above the switch elements of the power module, such that the contact force of the projection element is maximized at the switch elements.

9. The converter as claimed in claim 1, wherein a heat conducting paste is disposed between the heat sink and a waste heat surface of the power module.

10. The converter as claimed in claim 1, wherein the projection element is disposed centrally on the heat sink.

11. The converter as claimed in claim 1, wherein the wall portion of the cooling channel is formed of a spring steel material.

12. The converter as claimed in claim 1, wherein projection elements are formed in the wall portion of the cooling channel on each opposite side of the power module and project toward the power module.

13. The converter as claimed in claim 1, wherein the heat sink is also pressed at one end by a plastic part against the power module, wherein the plastic parts defines a frame for the power module and positions, aligns, and holds the power module.

14. The converter as claimed in claim 13, wherein the plastic part includes an incoming coolant channel connection and an outgoing coolant channel connection, through which the coolant respectively flows into and out of the cooling channel.

15. The converter as claimed in claim 14, wherein a first heat sink is disposed above the power module and a second heat sink is disposed below the power module, wherein the coolant flows from the inlet cooling channel connection into the cooling channel and through the first heat sinks, followed by flowing through the second heat sinks and out through the outlet cooling channel.

16. The converter as claimed in claim 13, wherein the plastic part combines with stamped sheet material of the cooling channel to define the flow path for the coolant.

17. The converter as claimed in claim 16, wherein the heat sink is fastened to the plastic part at edge regions of the power module, wherein the projection element is arranged over a central region of the power module.

18. The converter as claimed in claim 17, wherein the stamped sheets are bolted to the plastic part, wherein bolt forces hold the stamped sheets against the plastic part in a coolant tight manner, and the projection elements provide an inward force on the pressure surfaces of the heat sink.

19. The converter as claimed in claim 1, wherein an upper heat sink and a lower heat sink are provided in contact with the power module, wherein the pressure surface of the upper heat sink is at a top of the upper heat sink and the bottom of the upper heat contacts the power module, wherein the pressure surface of the lower heat sink is at a bottom of the lower heat sink and a top of the lower heat sink contacts the power module.

20. The converter as claimed in claim 19, wherein the upper heat sink receives an inflow of coolant through the cooling channel and the lower heat sink receives an outflow of coolant through the cooling channel.
